(19) United States
(12) Patent Application Publication
(10) Pub. No.: US 2009/0080166 A1
(43) Pub. Date: Mar. 26, 2009

(54) HANDHELD ELECTRONIC DEVICE WITH A MULTI-DIRECTIONAL KEY UNIT

(75) Inventor: Fei-Ming SU, Yuan-Lin Chen (TW)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: UNIVERSAL SCIENTIFIC INDUSTRIAL CO., LTD., Tsao-Tun Chen (TW)

(21) Appl. No.: 12/015,150

(22) Filed: Jan. 16, 2008

(30) Foreign Application Priority Data
Sep. 21, 2007 (TW) 096215943

(51) Int. Cl. H05K 5/00

(52) U.S. Cl. 361/752

(57) ABSTRACT

A handheld electronic device includes: a housing which has complementary first and second housing parts, and one corner formed with a key access hole; a screen mounted to the housing; and a multi-directional key unit which includes a circuit board mounted in the housing, a micro stick switch mounted on the circuit board and connected electrically thereto, and an operating control key coupled to the micro stick switch and disposed in the key access hole. The operating control key has outer dimensions smaller than dimensions of the key access hole so as to permit movement of the operating control key in multiple directions in the key access hole.

### BACKGROUND OF THE INVENTION

1. Field of the Invention

This invention relates to a handheld electronic device, more particularly to a handheld electronic device having a multi-directional key unit.

2. Description of the Related Art

Consumer desire for portable computers led to the creation of a handheld device called the Ultra-Mobile PC or UMPC. According to FIG. 1, the UMPC 10 is provided with a housing 11, a screen 12, and control keys 13 installed at the upper right and upper left corners of the housing 11.

During operation, the UMPC 10 is held in both hands and the forefingers are used to operate either of the control keys 13 to result in single directional movement of a target (such as a cursor).

Though the UMPC is indeed portable and useful, the single directional control associated with the control keys 13 detracts from the overall convenience of this device.

### SUMMARY OF THE INVENTION

Therefore, the object of the present invention is to provide a handheld electronic device having operating control keys capable of overcoming the aforementioned drawback of the prior art.

According to the present invention, there is provided a handheld electronic device that comprises: a housing which includes complementary first and second housing parts, and which has one corner formed with a key access hole; a screen mounted to the housing; and a multi-directional key unit which includes a circuit board mounted in the housing, a micro stick switch mounted on the circuit board and connected electrically thereto, and an operating control key coupled to the micro stick switch and disposed in the key access hole. The operating control key has outer dimensions smaller than dimensions of the key access hole so as to permit movement of the operating control key in multiple directions in the key access hole.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic top view of the conventional UMPC;

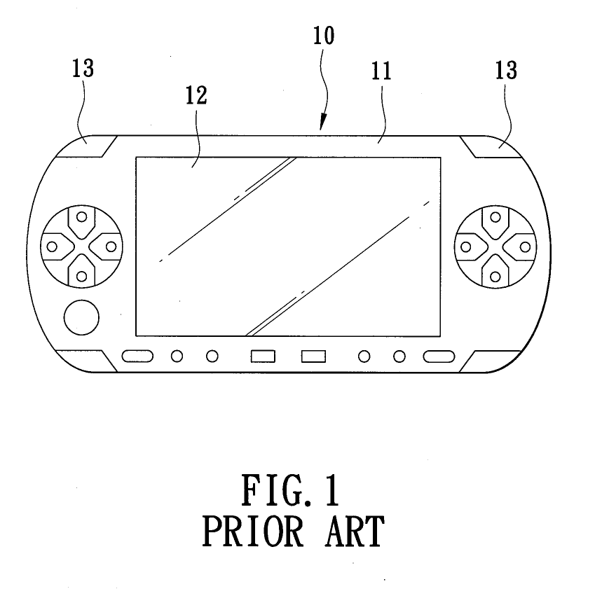

FIG. 2 is an exploded perspective view of a preferred embodiment of the handheld electronic device according to this invention;

FIG. 3 is a front perspective view of the handheld electronic device of FIG. 2;

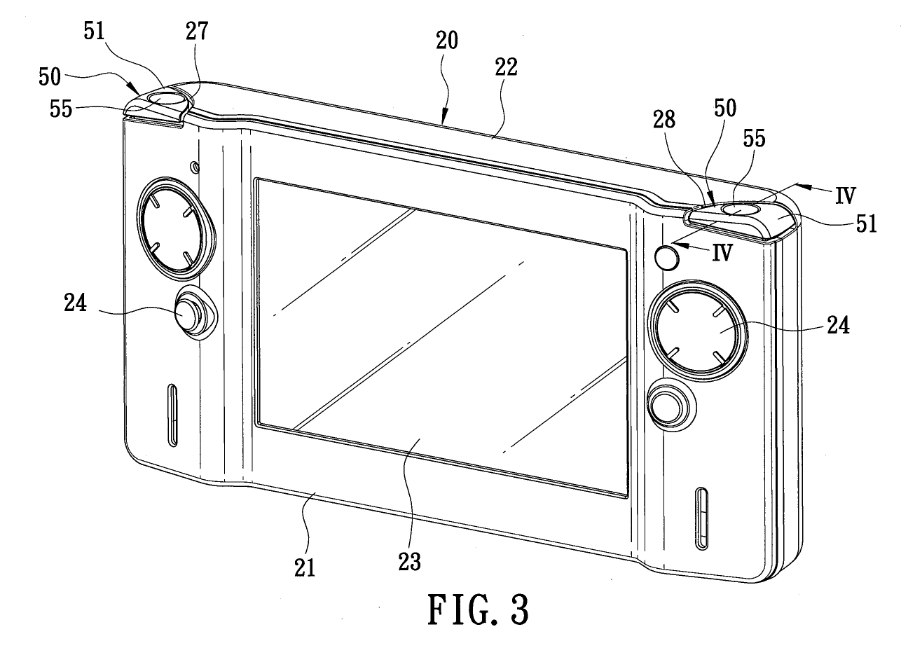

FIG. 4 is a cross-sectional view of the handheld electronic device, taken along line IV-IV in FIG. 3; and

FIG. 5 is a schematic front view illustrating how the handheld electronic device of FIG. 2 is to be operated.

### DETAILED DESCRIPTION OF THE PREFERRED EMBODIMENT

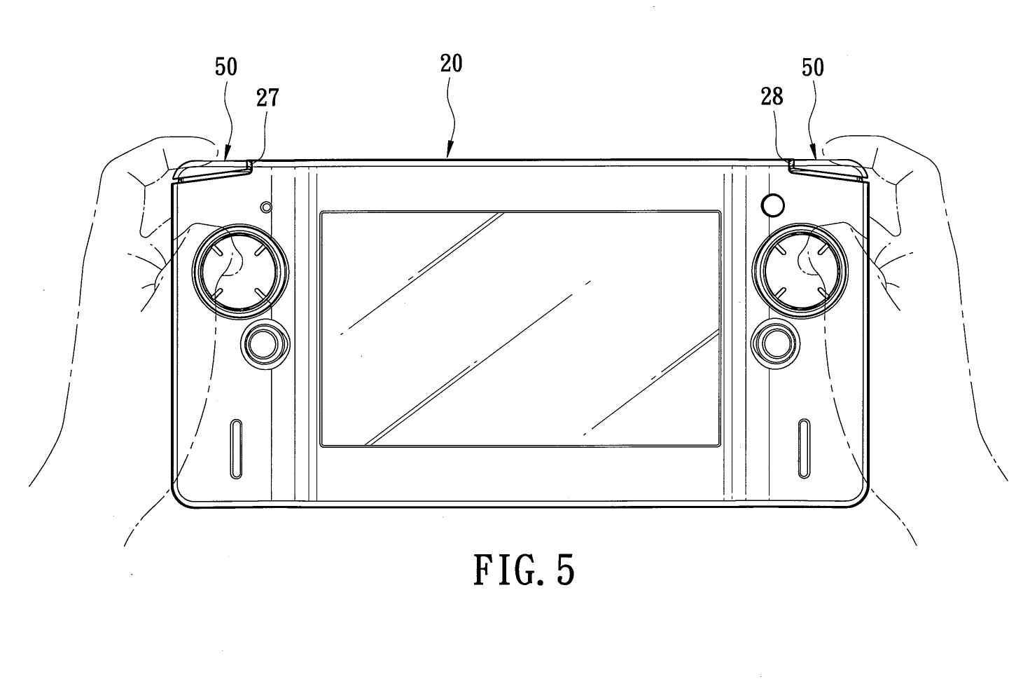

It should be noted herein that directional terminology, such as “top”, “bottom”, “left”, “right”, “front”, and “rear” are used in the following description in accordance with the conventional operating position of a preferred embodiment of a handheld electronic device illustrated in FIG. 5.

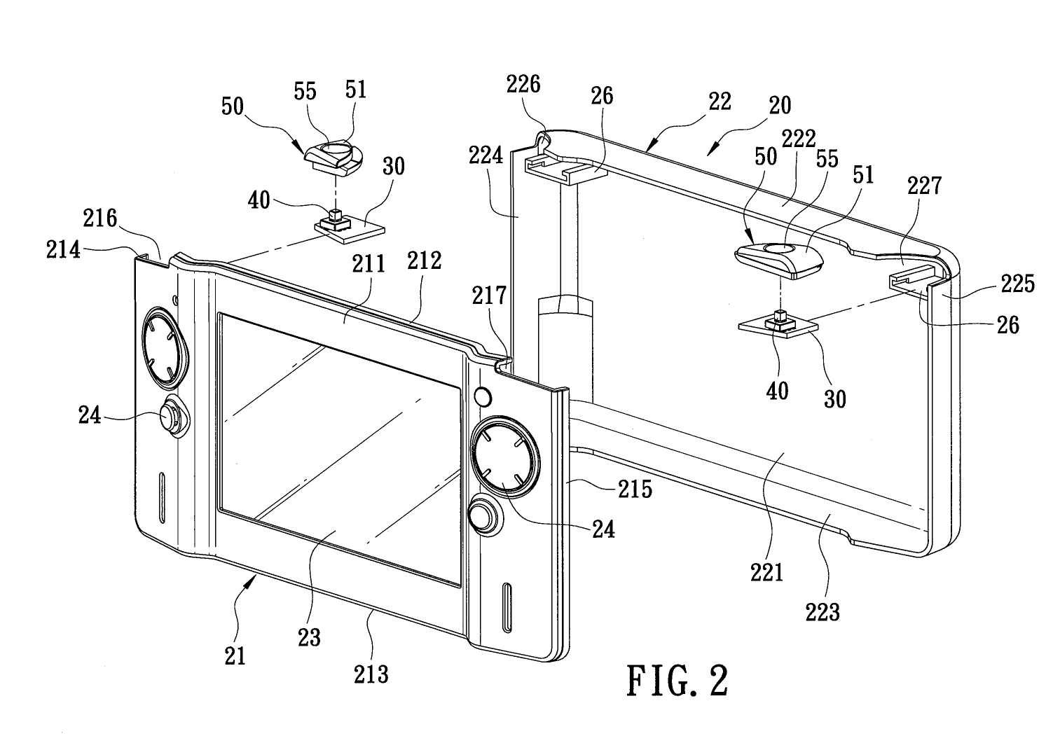

FIGS. 2,3,4, and 5 illustrate a preferred embodiment of a handheld electronic device according to this invention. The handheld electronic device comprises: a housing 20 which includes complementary first and second housing parts 21,22, and which has two corners formed with key access holes 27,28; a screen 23 mounted to the first housing part 21; a set of operating knobs 24 mounted to the first housing part 21; and two multi-directional key units which include two circuit boards 30 mounted in the housing 20, two micro stick switches 40 respectively mounted on the circuit boards 30 and connected electrically thereto, and operating control keys 50 respectively coupled to the micro stick switches 40 and respectively disposed in the key access holes 27,28. Each operating control key 50 has outer dimensions smaller than dimensions of the respective key access hole 27,28 so as to permit movement of the operating control key 50 in multiple directions in the respective key access hole 27,28.

In this embodiment, the first housing part 21 has a pair of first hole-defining wall sections 216,217, and the second housing part 22 has a pair of second hole-defining wall sections 226,227 that cooperate with the first hole-defining wall sections 216,217 to form the key access holes 27,28.

In this embodiment, the first housing part 21 includes a connecting plate 211 that has top, bottom, left and right edges, and top, bottom, left and right plates 212,213,214,215 that respectively extend from the top, bottom, left and right edges of the connecting plate 211 of the first housing part 21. The first hole-defining wall sections 216,217 are disposed at a junction of the connecting plate 211, the top plate 212, and a respective one of the left and right plates 214,215 of the first housing part 21.

The second housing part 22 includes a connecting plate 221 that has top, bottom, left and right edges, and top, bottom, left and right plates 222,223,224,225 that respectively extend from the top, bottom, left and right edges of the connecting plate 221 of the second housing part 22. The second hole-defining wall sections 226,227 are disposed at a junction of the connecting plate 221, the top plate 222, and a respective one of the left and right plates 224,225 of the second housing part 22.

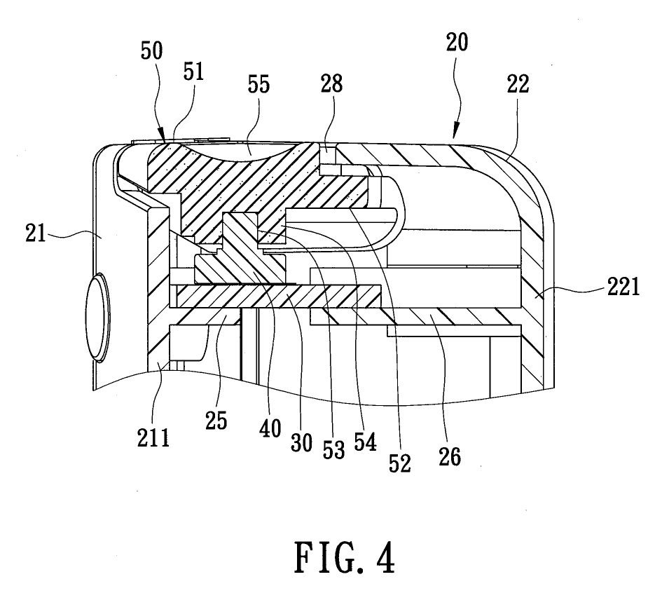

Preferably, the housing 20 further includes a pair of first guide rails 25 (only one is shown in FIG. 4) that extend from the connecting plate 211 of the first housing part 21 toward the second housing part 22 and that are respectively located under the first hole-defining wall sections 216, 217, and a pair of second guide rails 26 (see FIG. 2) that extend from the connecting plate 221 of the second housing part 22 toward the first housing part 21, that are respectively located under the second hole-defining wall sections 226, 227, and that are respectively aligned with the first guide rails 25. The circuit boards 30 are coupled insertingly to a respective aligned pair of the first and second guide rails 25,26 to position the circuit boards 30 in the housing 20.

Each micro stick switch 40 can be a known multi-directional switch operable for control in front, rear, left and right directions. Alternatively, each micro stick switch 40 can be a known multi-directional switch operable for control in the front, rear, left and right directions and further operable in a downward direction.

Preferably, each operating control key 50 has a top side 51 formed with a concave recess 55 to enhance touch sensation, a bottom side 52, and a coupling sleeve 54 (see FIG. 4) that extends from the bottom side 52 and that is formed with a coupling hole 53 for coupling with the respective micro stick switch 40.

During operation, the handheld electronic device of this invention is held in both hands and the forefingers are used to operate either of the operating control keys 50 to result in multi-directional movement of a target (such as a cursor) when playing games, browsing the Internet, etc., thereby resulting in enhanced convenience when the device of this invention is in use. While this invention has been exemplified using two multi-directional key units, it should be apparent to those skilled in the art that only one multi-directional key unit may be employed in other embodiments of this invention. In addition, the locations of the key access holes 27, 28 are not limited to be formed in the upper right and upper left corners of the housing 20 in other embodiments of this invention.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A handheld electronic device comprising:
a housing including complementary first and second housing parts, and having one corner formed with a key access hole;
a screen mounted to said housing; and
a multi-directional key unit including
a circuit board mounted in said housing,
a micro stick switch mounted on said circuit board and connected electrically thereto, and
an operating control key coupled to said micro stick switch and disposed in said key access hole, said operating control key having outer dimensions smaller than dimensions of said key access hole so as to permit movement of said operating control key in multiple directions in said key access hole.

2. The handheld electronic device as claimed in claim 1, wherein said first housing part has a first hole-defining wall section, and said second housing part has a second hole-defining wall section that cooperates with said first hole-defining wall section to form said key access hole.

3. The handheld electronic device as claimed in claim 2, wherein:
said first housing part includes a connecting plate that has top, bottom, left and right edges, and top, bottom, left and right plates that respectively extend from said top, bottom, left and right edges of said connecting plate of said first housing part;
said first hole-defining wall section being disposed at a junction of said connecting plate, said top plate, and one of said left and right plates of said first housing part;
said second housing part including a connecting plate that has top, bottom, left and right edges, and top, bottom, left and right plates that respectively extend from said top, bottom, left and right edges of said connecting plate of said second housing part;
said second hole-defining wall section being disposed at a junction of said connecting plate, said top plate, and one of said left and right plates of said second housing part.

4. The handheld electronic device as claimed in claim 3, wherein said housing further includes a guide rail that extends from said connecting plate of one of said first and second housing parts toward the other of said first and second housing parts, said circuit board being coupled to said guide rail to position said circuit board in said housing.

5. The handheld electronic device as claimed in claim 3, wherein said housing further includes a first guide rail that extends from said connecting plate of said first housing part toward said second housing part, and a second guide rail that extends from said connecting plate of said second housing part toward said first housing part and that is aligned with said first guide rail, said circuit board being coupled to said first and second guide rails to position said circuit board in said housing.

6. The handheld electronic device as claimed in claim 1, wherein said operating control key has a top side, a bottom side, and a coupling sleeve that extends from said bottom side and that is formed with a coupling hole for coupling with said micro stick switch.

7. The handheld electronic device as claimed in claim 6, wherein said top side of said operating control key is formed with a concave recess.

8. The handheld electronic device as claimed in claim 1, further comprising at least one operating knob mounted to said housing.
